(19) United States
(12) Patent Application Publication
(10) Pub. No.: US 2013/0043573 A1
(43) Pub. Date: Feb. 21, 2013

(54) Solder Bump Bonding In Semiconductor Package Using Solder Balls Having High-Temperature Cores

(71) Applicants: Richard K. Williams, Cupertino, CA (US); Keng Hung Lin, Kaohsiung (TW)

(72) Inventors: Richard K. Williams, Cupertino, CA (US); Keng Hung Lin, Kaohsiung (TW)

(73) Assignees: ADVANCED ANALOGIC TECHNOLOGIES (HONG KONG) LIMITED, Hong Kong (CN); ADVANCED ANALOGIC TECHNOLOGIES, INC., Santa Clara, CA (US)

(21) Appl. No.: 13/210,152

(22) Filed: Aug. 15, 2011

(51) Int. Cl. H01L 23/495; H01L 21/60

(52) U.S. Cl. 257/676; 438/613; 257/E23.031; 257/E21.506; 257/E21.509

(57) ABSTRACT

A semiconductor die is solder bump-bonded to a leadframe or circuit board using solder balls having cores made of a material with a melting temperature higher than the melting temperature of the solder to ensure that in the finished structure the die is parallel to the leadframe or circuit board.

### CROSS-REFERENCE TO RELATED APPLICATIONS

This application is related to application Ser. No. 11/381,292, filed May 2, 2006, titled “Bump-on-Leadframe (BOL) Package Technology with Reduced Parasitics,” which is incorporated herein by reference in its entirety.

### BACKGROUND OF THE INVENTION

Semiconductor chips or dice typically have contact pads on their surface which provide electrical access to the circuitry within the semiconductor die itself. Since these contact pads are very small, they are normally connected to an external printed circuit board, or the semiconductor die is enclosed within a package having leads that can readily be connected to external circuitry. One technique of making the connection between the contact pads on the die and the printed circuit board or package leads is referred to as “flip-chip” or “solder bump” bonding. With this technique, the die is oriented such that the surface of the die on which the pads are located, normally the top surface, is facing downward, and electrical connections are made between the contact pads and the circuit paths on the printed circuit board or the leads in the package by interposing solder balls or bumps between the die and the circuit paths or leads and then heating the solder balls or bumps. In this process, often referred to “reflowing,” the solder melts and adheres to the contact pads and the circuit paths or leads. The solder is then allowed to cool, forming a solid connection between the contact pads on the die and the circuit paths or leads.

The resulting structure is illustrated in FIGS. 1A and 1B. FIG. 1A shows a cross-sectional view of a chip-scale package (CSP) 1 that includes a printed circuit board (PCB) 2 and a semiconductor die 5. Printed circuit board 2 contains circuit paths 4A-4D which are separated by an insulating material 3, typically a polymer or composite material such as phenolic Contact pads 5A and 5B on the downward-facing surface of die 5 are electrically connected to circuit paths 4A and 4B via solder bumps 5A and 5B, respectively. In the areas not occupied by solder bumps 5A and 5B die 5 is separated from printed circuit board 2 by a space 7.

FIG. 1B shows a cross-sectional view of a flip-chip or bump-on-leadframe (BOL) semiconductor package 10. Package 10 includes a semiconductor die 13 and a leadframe 11 that includes leads 11A and 11B. Contact pads 13A and 13B on the downward-facing surface of die 13 are electrically connected to circuit paths 11A and 11B via solder bumps 14A and 14B, respectively. To complete the package 10, the assembly of die 13, solder bumps 14A and 14B and leads 11A and 11B is encapsulated in a plastic molding compound 12 that is typically formed in the shape of rectangular solid. Die 13 and leadframe 11 are separated by a region 15.

It will be noted that the external surfaces of leads 11A and 11B are coplanar with surfaces of the molding compound 12, giving package 10 a very compact form. Package 10 is therefore sometimes referred to as a “no-lead” package.

As described above, solder bumps 6A and 6B in CSP 1 and solder bumps 14A and 14B in no-lead package 10 are formed by reflowing solder balls that are initially positioned between the contact pads and the circuit paths or leads. One problem that may occur during the reflow process is that different solder balls may melt at uneven rates, resulting in a “coplanarity problem” between the die and the printed circuit board or leadframe.

The coplanarity problem is illustrated in FIGS. 2A and 2B. Chip-scale package 20 of FIG. 2A is similar to chip-scale package 1 of FIG. 1A, except that solder balls 21A and 21B melted at different rates during reflow, causing die 5 to be tilted in the final package. Likewise, no-lead package 30 of FIG. 2B is similar to no-lead package 10 of FIG. 1B, except that solder balls 31A and 31B melted at different rates during reflow, causing die 13 to be tilted in the final package.

Poor die coplanarity can cause degraded electrical and thermal conduction and lead to voids in the plastic molding compound, as shown by void 32 in FIG. 2B, or in the undercoating of the printed circuit board.

One method of avoiding the coplanarity problem is to use copper pillar bumps instead of solder bumps. As shown in FIG. 3, a copper-pillar bump-on-leadframe package 40 includes a semiconductor die 41 having contact pads 41A and 41B that are connected to leads 11A and 11B by means of copper pillars 42A and 42B and solder layers 43A and 43B. Unfortunately, copper pillar bumps are more expensive than solder balls and can create stress on the die. The added expense can best be understood by considering the steps needed to form a number of distinct copper pillars atop a silicon wafer and its die.

The copper pillar bump process involves numerous fabrication steps, each requiring processing time and material costs, with steps comprising the formation of an adhesion layer, followed by a masking operation to define the pillar locations, succeeded by copper plating, a subsequent adhesion etching of exposed adhesion layer metal, and finishing with a solder dipping process.

The purpose of the interfacial adhesion layer is to form a thin copper coating atop a fabricated silicon wafer to serve as a seed for promoting the electrochemical deposition, or electroplating, of copper. Since the top layer of most integrated circuits typically comprises primarily aluminum, electrical and chemical conditions to promote the electrochemical deposition of copper are difficult, if not impossible, to achieve, in part due to the intrinsic electrochemical potential difference, or work function, of the two materials. If the top metal layer is evaporated copper, electrochemical deposition of copper on to copper is easy since there is no difference of the material being deposited and the material on which it is being deposited.

Unfortunately, direct contact between copper and aluminum is not desirable since the combination of aluminum, copper and silicon materials can form intermetallic alloys that are mechanically brittle and poor in electrical conductivity. One such intermetallic, known as the “purple plague”, was problematic in the early years of semiconductors, confounding manufacturers and frustrating reliability engineers. The solution is to introduce a diffusion barrier and adhesion promoter, such as tungsten, platinum, titanium, or palladium, deposited by sputtering prior to copper deposition. The extra deposition adds cost.

After the interfacial adhesion sandwich layer is deposited, a thick photoresist layer is applied, patterned using photolithography, and developed to remove the resist above the regions where the copper pillar is to be electroplated. Electrochemical deposition occurs only where the photoresist is removed, exposing the underlying copper layer. After developing, the photoresist must be baked at a sufficiently high temperature to harden it against removal or erosion during electroplating where the wafer remains submerged in a chemical batch for several hours.

Copper electroplating is next performed by biasing the wafer and the copper carrying electrolyte to conduct current and in so doing transport copper ions from solution to the wafer surface where they are adhere to form a growing layer of copper. Since deposition rates are constrained by safe current levels of a few amperes, deposition rates typically are slower than 1 μm per minute, meaning the deposition of a copper pillar of 100 to 200 μm can take several hours to complete.

After electroplating, the photoresist is removed. Since however the resist was “hard baked” at a high temperature its removal requires a slow process called “ashing”, a process performed in an expensive machine similar to plasma etching. This step adds further cost to the pillar bump formation.

After photoresist removal, the exposed interfacial adhesion layer of copper and the barrier metal must be removed by wet chemical means or by sputter etching, adding further cost to the process. Inadequate removal of this layer can also leads to electrical shorts between the pillars, lowering test yields and raising product costs.

Finally, the copper pillars are coated in solder such as lead-tin (Pb—Sn), tin (Sn), or silver (Ag). One such means to apply the solder selectively to the tops of the copper pillars can be achieved by dipping the pillars into a liquid solder bath without submerging the wafer. Process control can be difficult to ensure the pillars penetrate the solder uniformly across the entire wafer. Improper handling can lead to yield loss from wafer breakage.

After the entire process, a completed wafer with copper pillars and solder tips has been manufactured and is now ready for singulation through sawing and subsequent bonding onto the leadframe or PCB. During the sawing process, some of the pillars may fall off due to handing or mechanical damage or due to intrinsic film stress present between the stiff copper pillar and the more flexible silicon wafer. Missing pillars constitutes another form of yield loss and product expense.

Thick copper pillars, especially large areas, can also cause stress induced damage and cracks in the silicon, in glass layers, and in interfacial layers, either during wafer fabrication, in subsequent manufacturing heat treatments, or in normal operation during temperature or power cycling. The stress failures occur because silicon and copper exhibit differing levels of ductility and Young's Modulus. The stress is further exacerbated over temperature because of dissimilar temperature coefficients of expansion for copper, silicon, and dielectrics such as silicon dioxide and silicon nitride. Stress fractures are fatal, representing more than a yield loss, but possibly causing reliability failures for products shipped to customers or operating in the field. While changing the aspect ratio and shape of the copper pillars can reduce stress, stress concerns and reliability risk remains problematic for the consistent high volume manufacturing of pillar bump silicon wafers and their application in bump-onto-leadframe packages.

Accordingly, there is a need for a simple, effective, inexpensive and reliable method for avoiding the die coplanarity problem in chip-scale and bump-on-leadframe packages.

### BRIEF SUMMARY OF THE INVENTION

The die coplanarity problem is avoided in a semiconductor package according to this invention. In a bump-on-leadframe package, an electrical connection between a contact pad on a semiconductor die and a lead comprises solder surface layer and a high-temperature core, the high-temperature core being laterally surrounded by the solder surface layer and having a higher melting temperature than the solder surface layer. The term “high temperature core” shall, in the context of this disclosure, be generally understood to mean any material that does not melt, decompose, or otherwise deform or substantially lose its shape at the temperature where the solder melts.

It is also understood that while the solder may substantially surround and encase the high temperature core initially, that during attachment of the die to a leadframe or circuit board conductive trace, the solder may flow and redistribute itself during bonding such that the solder may no longer completely encases or uniformly surrounds the high temperature core.

In a chip-scale package, an electrical connection between a contact pad on a die and a conductive circuit path in a circuit board comprises a solder surface layer and a high-temperature core, the high-temperature core being laterally surrounded by the solder surface layer and having a higher melting temperature than the solder surface layer.

The invention also includes a method of forming an electrical connection between a contact pad on a semiconductor die and an external circuit path. The method comprises: providing a solder ball, the solder ball comprising a high-temperature core of a high-temperature material and a solder shell, the high-temperature core being enclosed by the solder shell, the high-temperature material having a higher melting temperature than the solder shell; positioning the solder ball such that the solder ball is in contact with the contact pad and the external circuit path; and heating the solder ball to a temperature above the melting temperature of the solder but below the melting temperature of the high-temperature material.

The invention also includes several embodiments of the high temperature core, whereby the core may comprise a conductor such as a metal, or and insulating material such as a glass, ceramic, or plastic.

### BRIEF DESCRIPTION OF THE SEVERAL VIEWS OF THE DRAWING

The invention will be better understood by reference to the following drawings, which are not necessarily drawn to scale and in which like reference numerals designate similar components.

FIGS. 1A and 1B are cross-sectional views of a conventional chip-scale package and a conventional bump-on-leadframe package, respectively.

FIGS. 2A and 2B are cross-sectional views illustrating the coplanarity problem in a conventional chip-scale package and a conventional bump-on-leadframe package, respectively.

FIG. 3 is a cross-sectional view of a conventional copper-pillar bump-on-leadframe package.

FIG. 4 is a cross-sectional view of a no-lead package in accordance with the invention.

FIG. 5A is a three-dimensional cutaway view of a solder ball according to the invention.

FIGS. 5B and 5C are cross-sectional views of the solder balls.

FIGS. 6A-6C illustrate a process of fabricating a package in accordance with the invention.

FIGS. 7A-7E are cross-sectional views of various types of leaded and no-lead packages in accordance with the invention.

FIGS. 8A and 8B are a plan view and a cross-sectional view, respectively, of a chip-scale package in accordance with the invention.

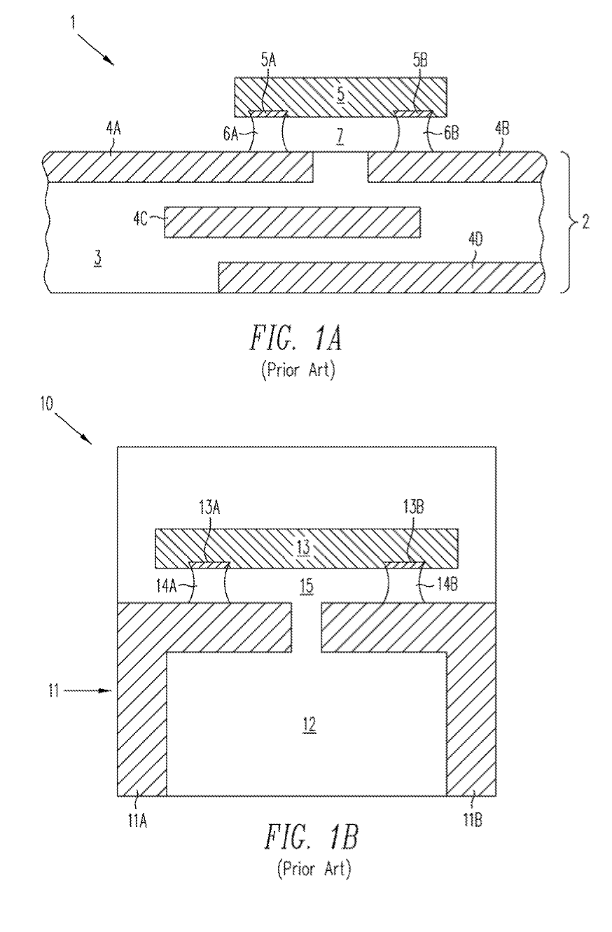

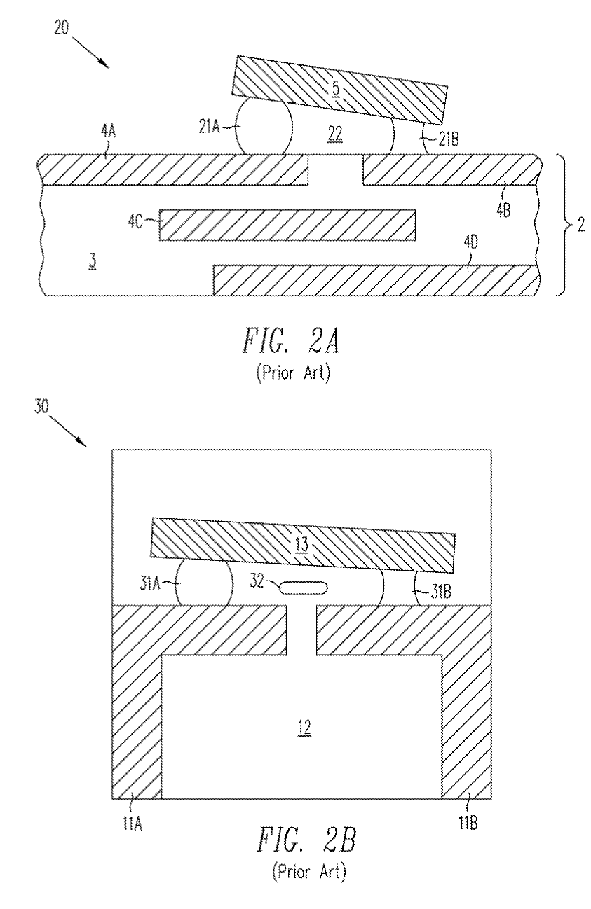

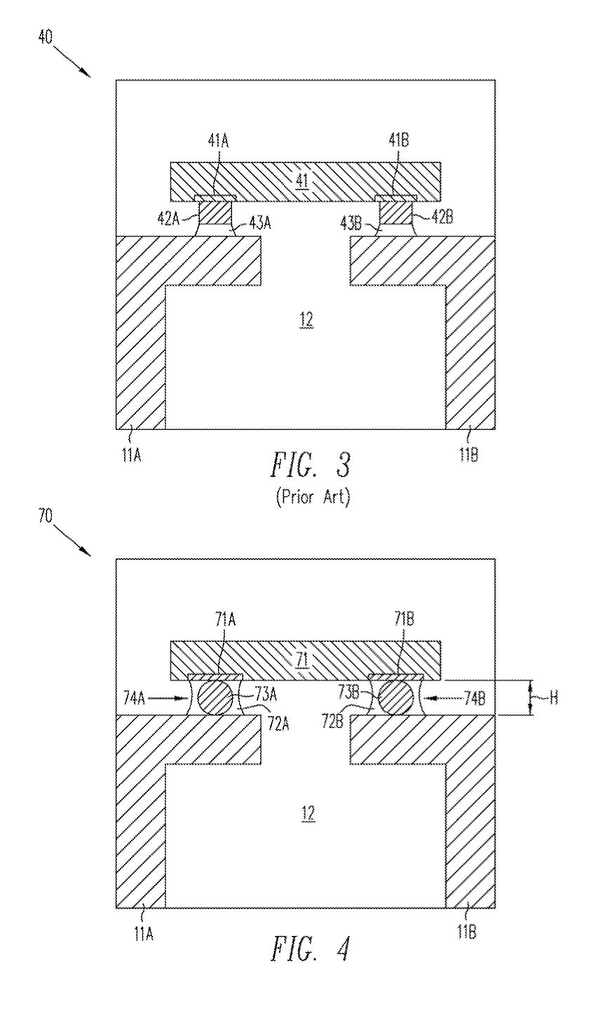

### DETAILED DESCRIPTION OF THE INVENTION

An exemplary no-lead package 70 in accordance with the invention is shown in FIG. 4. A semiconductor die 71 includes contact pads 71A and 71B. Contact pad 71A is connected to lead 11A by means of an electrical connection 74A. Contact pad 71B is connected to lead 11B by means of an electrical connection 74B. Each of electrical connections 74A and 74B comprises a solder surface layer and a high-temperature core, the high-temperature core being laterally surrounded or substantially surrounded by solder surface layer. Thus, in electrical connection 74A, a high-temperature core 73A is laterally surrounded by a solder surface layer 72A. In electrical connection 74B, a high-temperature core 73B is laterally surrounded by a solder surface layer 72B. Cores 73A and 73B have the same vertical dimension H and are preferably of the same size and shape.

In many embodiments the high-temperature core will be spherical, as shown by cores 73A and 73B in FIG. 4, but this need not be the case. If the high-temperature core is spherical, the vertical dimension of the core will be equal to the diameter of the sphere.

The solder surface layer 72A is in contact with contact pad 7IA and lead 11A such that the high-temperature core 73A is completely enclosed by the lead 11A, the contact pad 71A and the solder surface layer 72A. The high-temperature core 73A has a higher melting temperature than the solder surface layer 72A. Similarly, the solder surface layer 72B is in contact with contact pad 71B and lead 11B such that the high-temperature core 73B is completely enclosed by the lead 11B, the contact pad 71B and the solder surface layer 72B. The high-temperature core 73B has a higher melting temperature than the solder surface layer 72B.

The term “high temperature core” shall therefore, in the context of this disclosure, be generally understood to mean any material that does not melt, decompose, or otherwise deform or substantially lose its shape at the temperature where the solder melts. For example is the core were to become soft at the solder melting temperature, as long as it does not substantially change its shape, i.e. substantially physically deform, then it will be generally understood that the core has not “melted”.

As described below, during the fabrication of no-lead package 70 the temperature does not reach the melting temperature of the high-temperature cores 73A, 73B. Thus, the high-temperature cores 73A, 73B remain in the solid state and define the distance between die 71 and leads 11A, 11B in the finished package. Since cores 73A, 73B are the same size, the lower surface of die 71 is parallel to the top surfaces of leads 11A, 11B, thereby avoiding the coplanarity problem.

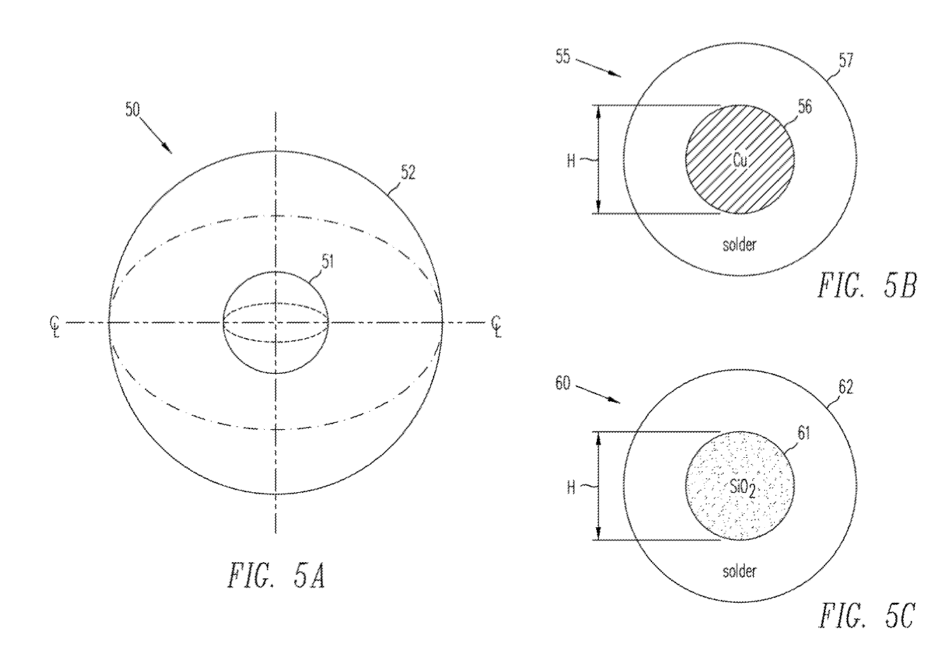

In the process of fabricating package 70, the electrical connections 74A, 74B are initially in the form of solder balls having high-temperature cores. FIG. 5A is a three-dimensional cutaway view of a solder ball 50 that contains a high-temperature core 51 surrounded by a solder shell 52. Solder shell 52 encloses high-temperature core 51.

High-temperature core 51 has a melting temperature that is higher than the melting temperature of solder shell 52. Various types of solder are well known in the art. For example, solder may be made of tin, silver or gold, or may be alloys or binary compounds of these metals, such as lead-tin (Pb—Sn) solder. The term “solder,” as used herein, refers to any metal or metallic compound or alloy that is melted and then allowed to cool in order to join two or more metallic surfaces together. Generally speaking, solders have melting temperatures in the range of 150 to 250° C.

High-temperature core 51 can be made of any material that has a melting temperature that is higher than the melting temperature of the solder used for solder shell 52. Possible materials for core 51 are metals such copper, aluminum and the refractory metals; ceramic materials; and silicon dioxide. It will be evident that the word “high” in the term “high-temperature core” is used not in an absolute sense but rather in a comparative sense as meaning that the melting temperature of the core is higher than the melting temperature of the solder shell.

FIG. 5B is a cross-sectional view of a solder ball 55 with solder shell 57 and a high-temperature core 56 made of copper. FIG. 5C is a cross-sectional view of a solder ball 60 with solder shell 62 and a high-temperature core 61 made of silicon dioxide.

Formation of a solder ball with a high temperature core can be made by any number of means. For example, the core can be made by molding, whereby liquid metal, glass, or plastic is injected into a high-temperature mold comprising numerous cavities or chambers connected by a network of tubes or capillaries. After the material is injected to fill all of the cavities, the material is allowed to cool, thereby taking the shape of the mold container, also known as a mold chase. The cores are subsequently removed in preparation for solder coating.

Other high volume methods exist for creating high temperature cores without requiring molding or a mold chase. One such method utilizes a ballistic method to “shoot” small droplets of molten material out of nozzles in bursts. With such a ballistic injection method, each droplet spontaneously forms a nearly spherical shape immediately after being expulsed from the injector nozzle, a natural phenomenon of a liquid that minimizes surface tension. Controlling the flow rate, pulse rate, and backpressure determines the amount of material discharged per pulse, and can through process control and feedback be used to control the size of the resulting core.

Non metallic high temperature cores, e.g. comprising ceramic, glass or plastic, may be infused with metallic particles prior to molding, for example by mixing copper “dust” into ceramic powder before sintering. These metallic particles help facilitate regions of metallic atoms exposed on the surface of the core making it easier to subsequently coat the high temperature core with solder. Alternatively, non-conductive cores may be flash evaporated with a metal film or dipped in glue containing metallic particles to improve solder adhesion.

Once prepared, the high temperature cores are ready to be coated in solder, i.e. the high temperature core is coated with a layer of solder, herein referred to as a solder “shell”. One high volume method for coating the cores involves dipping the cores in a bath of molten solder. The dipping time and extraction rate, along with the temperature and viscosity of the solder can be used to control the thickness of the resulting solder layer adhering to the high temperature core.

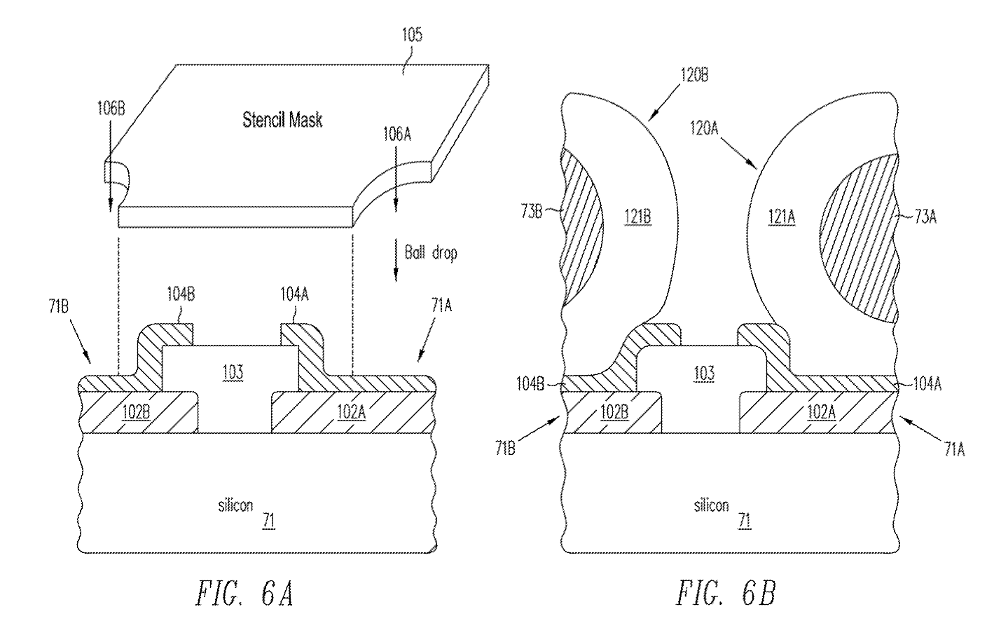

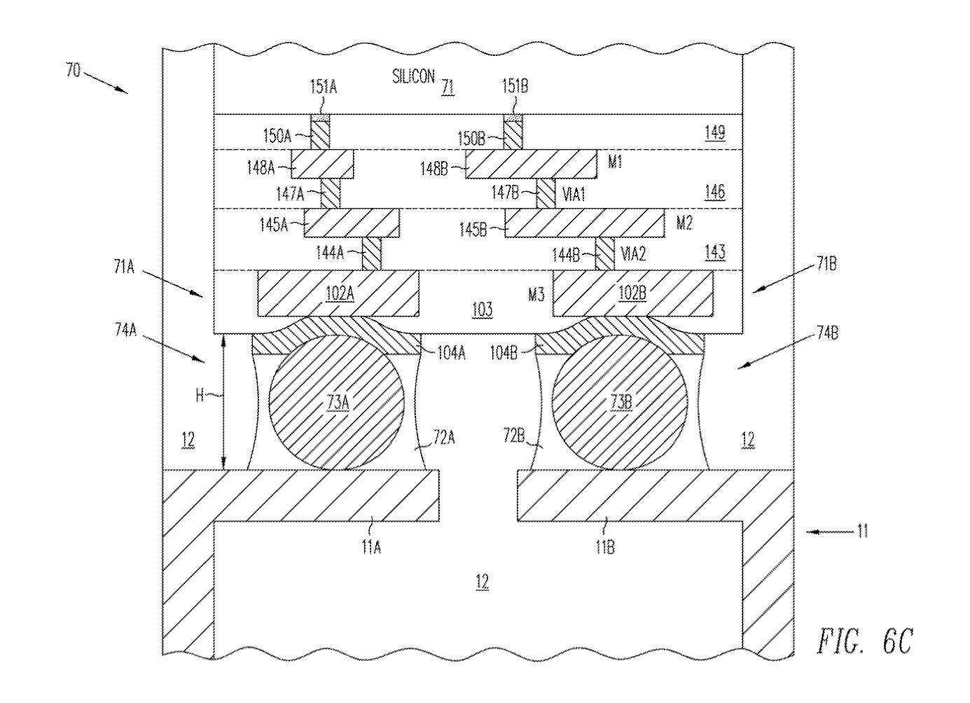

Alternatively, the solder can be “grown” in a chemical batch using electroless chemical plating techniques. Electroless depositions, unlike electroplating methods, do not involve or require a conducting current to facilitate material deposition and growth. FIGS. 6A-6C illustrate a process of fabricating electrical connections 71A and 71B in the package 70 shown in FIG. 4. FIG. 6A shows the die 71 with the contact pads 71A and 71B facing upward, so that contact pad 71A appears on the right and contact pad 71B appears on the left. As shown, contact pad 71A actually includes a metal layer 102A and an under bump metal (UBM) 104A, which has a concave upper surface that generally is sized so as to receive the solder balls used in the process. Similarly, contact pad 71B includes a metal layer 102B and a UBM 104B, which has a concave upper surface similar to the upper surface of UBM 104A. The pad areas are laterally separated by a glass or insulator material 103, having a lateral width, at a minimum of sufficient spacing to prevent solder balls 73A and 73B from shorting together, and generally of a dimension consistent with the package pin pitch so as to align the solder balls to their associated lead frame for bonding. A stencil mask 105 is positioned above die 71. Stencil mask 105 has openings 106A and 106B that are positioned so as to correspond to contact pads 71A and 71B and dimensioned so as to allow the solder balls (see below) to pass through openings 106A and 106B.

Solder balls 120A and 120B are allowed to drop through openings 106A and 106B. As a result, solder ball 120A nests in UBM 104A and solder ball 120B nests in UBM 104B, as shown in FIG. 6B. Solder ball 120A includes a solder shell 121A enclosing a high-temperature core 73A, and solder ball 120E includes a solder shell 121B enclosing a high-temperature core 73B. Stencil mask 105 is then removed.

Contact pads 71A and 71B may optionally be pre-heated sufficiently to slightly melt or soften the outer skins of solder shells 121A and 121B, causing solder balls 120A and 120B to adhere to UBMs 104A and 104B. If solder shells 121A and 121B are made of a Pb—Sn solder, for example, this could be done by pre-heating contact pads 71A and 71B to 175° C. in a steady state condition while the balls are dropped onto the die. In practice, an entire silicon wafer is heated by a hot chuck that holds the wafer, and the stencil mask drops balls across the entire wafer at one time. After the pre-heating, solder shells 121A and 12IB conform to the shape of UBMs 104A and 104B, as shown in FIG. 6B.

The ball drop process is typically performed one wafer-at-a-time using a wafer-track based production system where wafers constantly are fed into machine placed onto the hot chuck, the solder balls are dropped onto the wafer through the stencil mask, and finally the completed wafer is removed, while the next wafer is then loaded onto the chuck. Wafers may be preheated using infrared lamps prior to their loading on to the chuck to reduce the time for temperature stabilization on the hot chuck thereby reducing the per wafer processing time and improving manufacturing throughput. While the methods of solder ball drop “bumping” of a wafer are known to those skilled in the art, the processing of non-homogenous solder balls such as solder balls with a high temperature cores are not known.

After the ball drop is completed on a wafer, the wafer is sawed into separate dice, also called “bumped” die. In semiconductor packaging and assembly vernacular, the term bumped is a topographic reference a die with a surface that is bumpy and not flat because of solder balls or pillar bumps attached to its surface.

Assembly of the bumped die onto a leadframe occurs by using a pick-and-place machine to pick up the bumped die, one by one, and place them onto a leadframe containing the leads for numerous packaged devices. In conventional semiconductor assembly, the die are picked up and mounted onto the leadframe on a metallic die pad in a “backside down” configuration, where the back of the silicon die, not the side with the metal pads, are attached onto the leadframe.

In contrast, in a “bump-onto-leadframe” or BOL assembly method used in the disclosed invention, the bumped die must be flipped over, i.e. inverted, such that the pad side of the die faces downward onto the leadframe. This front-side down pick-and-place die attach operation can also be referred to as flip-chip assembly. While the methods of flip chip assembly are known to those skilled in the art, the processing of non-homogenous solder balls such as solder balls with a high temperature cores are not known.

In accordance with flip chip assembly, die 71 is then inverted, so that contact pads 71A and 71B are facing downward, and solder balls 120A and 120B are allowed to rest on leads 11A and 11B, which at this stage of the process would be part of a leadframe 11 as shown in FIG. 4. Leadframe 11 is then heated. This causes solder shells 121A and 121B to melt, and with solder shells 121A and 121B liquefied, surface tension forces die 71 and high-temperature cores 73A and 73B downward until UBMs substantially rest on cores 73A and 73B and cores 73A and 73B rest on leads 11A and 11B, respectively. The resulting structure, after the solder is allowed to cool, is shown in FIG. 6C. It will be seen that solder shells 121A and 121B have been deformed under the influence of the heat to become solder surface layers 72A and 72B within package 70, as shown in FIG. 4.

It should be noted that while FIG. 4 shows high temperature cores 73A and 73B physically resting directing on leadframe metal 11A and 11B, in reality some solder might actually remain as an interfacial layer between the high temperature core and the leadframe. After heating, any surviving intervening solder layer will, in practice, be negligibly thin because surface tension naturally forces the melted solder to redistribute to the sides of the cores and rather than remaining between the core and the underlying leadframe. In fact, any significant thickness of solder-residue remaining interposed between the core material and the leadframe is indicative of a manufacturing problem, namely that the solder was not heated sufficiently to fully redistribute itself. Such a “cold solder” joint, in addition to causing poor coplanarity between the die and the leadframe, can lead to degraded or unreliable electrical connections between the die and the package leads. It can also result in poor thermal resistance and overheating of the product in actual operation:

Sufficient heating of the die and leadframe during bump-onto-leadframe die attach is important to achieve consistent results from BOL assembly. In volume manufacturing, consistent solder flow heating comprises more than simply applying a fixed temperature for a set duration. Instead, BOL die attach of the die and leadframe are generally heated by varying the temperature sequentially in a prescribed manner known as a “solder profile,” i.e., a chart of temperature versus time used in the solder reflow furnace.

One common solder profile involves (1) heating the die-leadframe assembly to a fixed temperature below the solder melting point for several minutes to half-an-hour, (2) ramping the temperature up at a fixed rate to a prescribed temperature above the solder melting point, (3) holding the leadframe at that temperature for a prescribed period of time, e.g. ten minutes, (4) ramping the temperature back down to a temperature below the melting point, and (5) holding the leadframe at the sub-melting point temperature for a prescribed period of time, e.g. ten minutes, and (6) removing the newly soldered assembly from the furnace or oven.

While this temperature profile can be achieved in a fixed enclosure oven using closed-loop electronic control of the oven's heating element, such a profile can easily be achieved by running the leadframe through a multi-zone furnace on a moving track or conveyer belt. Such multi-zone belt furnaces can easily produce the aforementioned thermal solder profile, or other profiles, simply by controlling the belt rate and the physical length and temperature within each heating zone. Belt furnaces support continuous flow manufacturing without the need to stop an operation to load or unload the material.

The actual temperature profile needs to insure proper solder flow and die attach varies with the composition of the solder. Solder alloys such as lead-tin tend to have lower melting points, for example in the 150° C. to 175° C. range, while lead-free solders such as pure tin or silver can have melting points exceeding 200° C. Tables of solder melting points and recommended solder profiles are commercially available from solder manufacturers and from publically available books, journals and on-line references.

Semiconductor BOL assembly of BOL packages has been adapted from the methods originally used in printed circuit board manufacturing. The requisite solder profiles applicable for BOL assembly with conventional solder balls should be generally applicable to BOL assembly of dice using solder balls with high temperature cores, as disclosed herein.

FIG. 6C shows additional detail on the surface of die 71 for exemplary purposes, illustrating the relationship between the resulting structure comprising a BOL assembly using solder balls with high temperature cores, and a silicon die comprising an integrated circuit with multiple layers of metal interconnections. Contact pads 71A and 71B are separated from the surface of the silicon by interlayer dielectrics 143, 146 and 149. Contact pad 71A is connected to a metal layer 145A (part of M2) through a metal-filled via 144A in interlayer dielectric 143. Metal layer 145A is connected to a metal layer 148A (part of M1) through a metal-filled via 147A in interlayer dielectric 146. Metal layer 148A is connected to the surface of the silicon through a metal-filled via 150A in interlayer dielectric 149. A silicide barrier layer 151A is located at the surface of the silicon.

Similarly, contact pad 71B is connected to a metal layer 145B (part of M2) through a metal-filled via 144B in interlayer dielectric 143. Metal layer 145B is connected to a metal layer 148B (part of M1) through a metal-filled via 147B in interlayer dielectric 146. Metal layer 148B is connected to the surface of the silicon through a metal-filled via 150B in interlayer dielectric 149. A silicide barrier layer 151B is located at the surface of the silicon. The number of metal interconnect layers within a semiconductor die may vary from one metal layer to as many as a dozen layers. The disclosed invention is applicable to any semiconductor die regardless of the number of interconnection layers that it contains.

Normally, a number of dice would be connected to other leads in leadframe 11 in a manner similar to that described above. The dice and leads are encased in a plastic molding compound by an injection process, and the individual dice are then separated into individual packages (singulated) by sawing through the leadframe and molding compound at appropriate locations. The injection molding and singulation processes are well known in the art and will not be described in detail here.

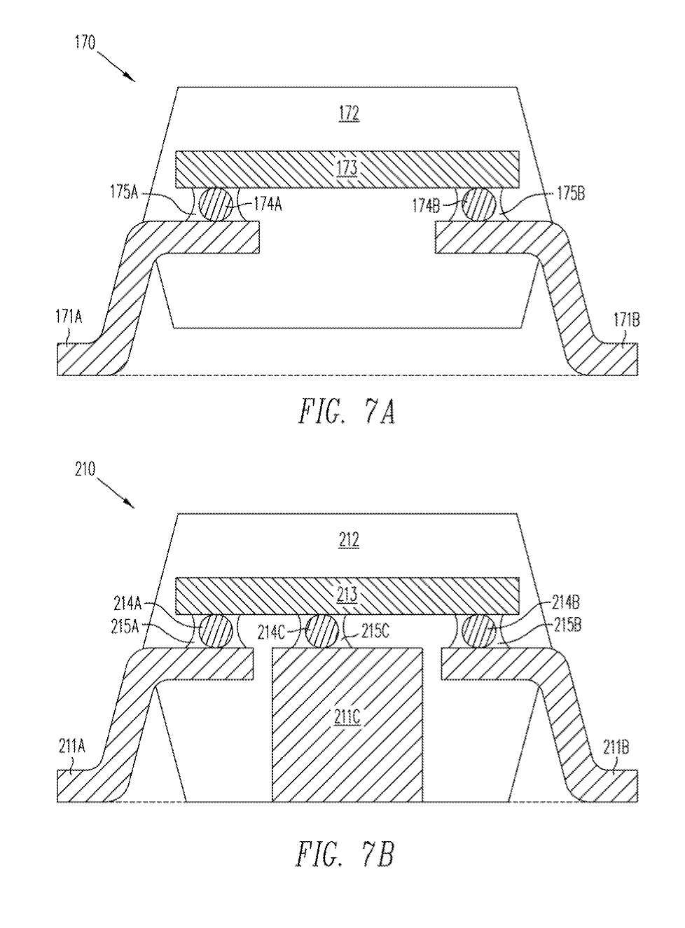

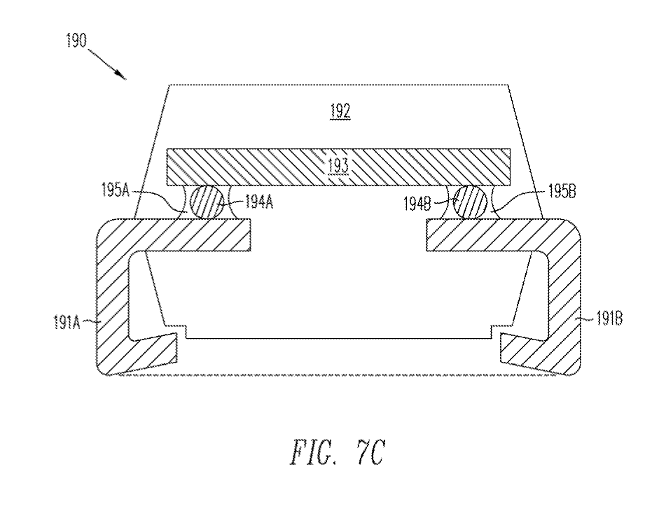

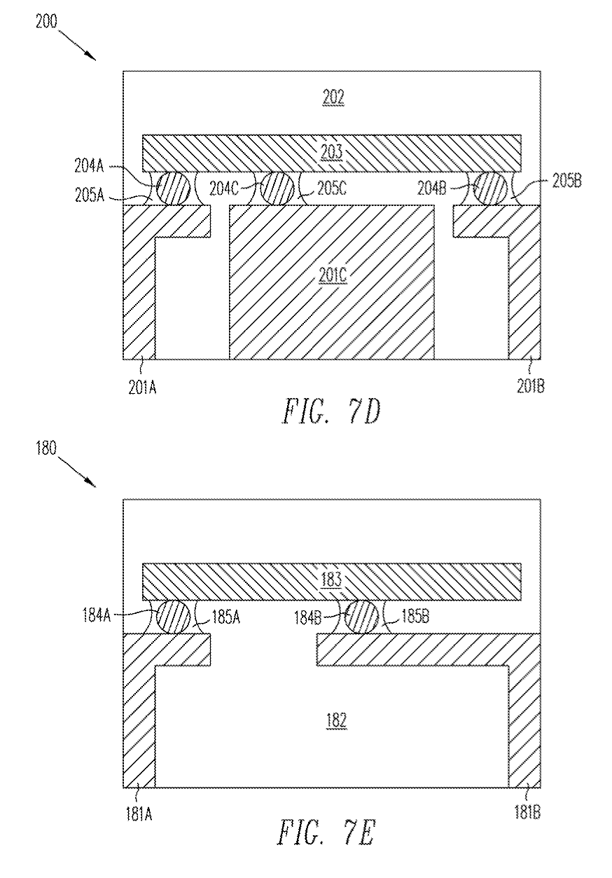

The technique of this invention has wide application to a variety of leaded and no-lead BOL packages. A few examples of these packages are illustrated in FIGS. 7A-7E.

FIG. 7A illustrates a cross-sectional view of a leaded package 170 with leads 171A and 171B in the shape of gull wings. Package 170 includes a semiconductor die 173 that is connected to leads 171A and 171B by solder surface layers 175A and 175B and high-temperature cores 174A and 174B. Die 172 is encased in a molding compound 172.

FIG. 7B illustrates a cross-sectional view of a leaded package 210 that is similar to package 170 of FIG. 7A except that package 210 contains a heat slug 211C for transferring heat from die 213, and the lower surface of the molding compound 212 is coplanar with the lower mounting surfaces of leads 211A and 211B. Otherwise, package 210 contains gull-winged leads 211A and 211B, which are connected to die 213 by means of solder surface layers 215A and 215B and high-temperature cores 214A and 214B. Heat slug 211C is connected to die 213 by means of a solder surface layer 215C and a high-temperature core 214C. The combination of solder surface layer 215C and a high-temperature core 214C may provide an electrical as well as thermal contact with die 213. The coplanarity of the lower surface of the molding compound 212 and the lower mounting surfaces of leads 211A and 211B facilitates the use of heat slug 211C to transfer heat from die 213 to a surface on which package 210 is mounted.

FIG. 7C illustrates a cross-sectional view of a leaded package 190 that is similar to package 170 of FIG. 7A except that leads 191A and 191B are in the shape of a reverse gull wing or “J.” Package 190 includes a semiconductor die 193 that is connected to leads 191A and 191B by solder surface layers 195A and 195B and high-temperature cores 194A and 194B. Die 192 is encased in a molding compound 192.

FIG. 7D illustrates a cross-sectional view of a no-lead package 200 that is similar package 70 of FIG. 4 except that package 200 contains a heat slug 201C for transferring heat from die 203. Otherwise, package 210 contains leads 201A and 201B, which are connected to die 203 by means of solder surface layers 205A and 205B and high-temperature cores 204A and 204B. Heat slug 201C is connected to die 203 by means of a solder surface layer 205C and a high-temperature core 204C. The combination of solder surface layer 205C and a high-temperature core 204C may provide an electrical as well as thermal contact with die 203. The coplanarity of the lower surface of the molding compound 202 and the lower mounting surfaces of leads 201A and 201B facilitates the use of heat slug 201C to transfer heat from die 203 to a surface on which package 200 is mounted.

FIG. 7E illustrates a cross-sectional view of a no-lead package 180 that is similar to package 70 of FIG. 4 except that package 180 is asymmetrical in that lead 181A is not the same size and shape of opposite lead 181B. Otherwise, package 180 contains a die 183 which is connected to leads 181A and 181B by means of solder surface layers 185A and 185B and high-temperature cores 184A and 184B.

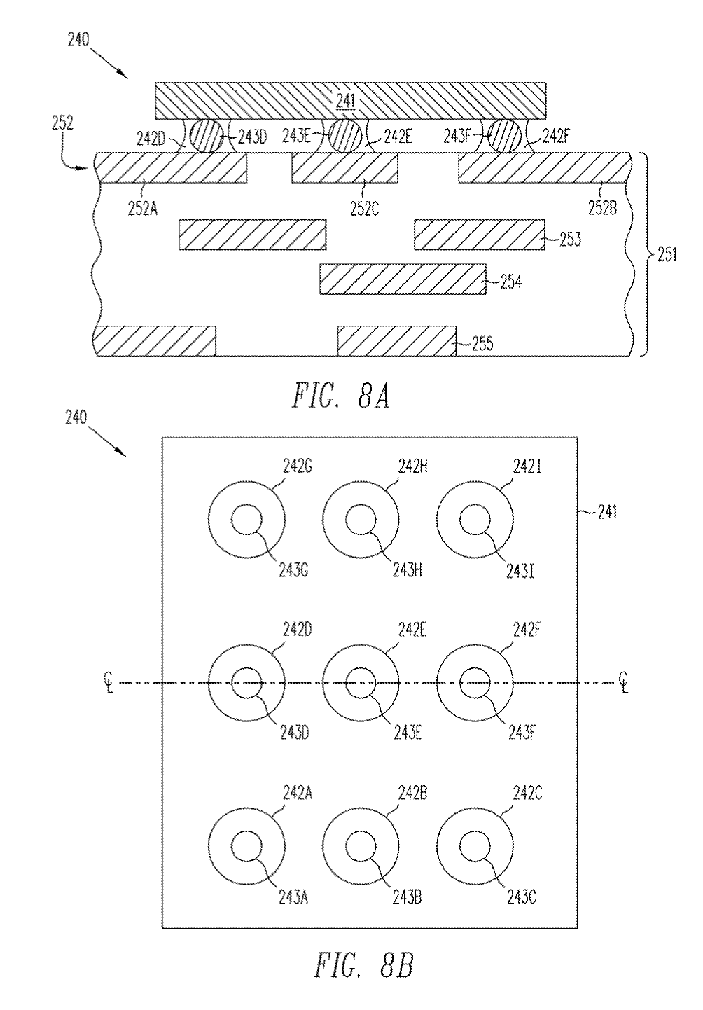

The invention is also applicable to a variety of chip-scale packages. FIGS. 8A and 8B illustrate a chip-scale package (CSP) 240. FIG. 8A is a cross-sectional view of CSP 240 showing a die 241 connected to a printed circuit board 251. FIG. 8B is a plan view of die 241 and a 3×3 array of high-temperature cores 243A-243I that are surrounded by solder surface layers 242A-242I, respectively. As indicated, FIG. 8A is taken at the section the coincides with the centerline of the 3×3 array, namely through high-temperature cores 243D-243F and solder surface layers 242D-242F.

Printed circuit board 251 includes metal layers 252-255. Die 241 is connected to metal circuit paths 252A, 252B and 252C in metal layer 252.

The above description is intended to be illustrative and not limiting. Many alternative embodiments of this invention will be apparent to persons of skill in the art. The broad principles of this invention are defined only in the following claims.

We claim:

1. A bump-on-leadframe semiconductor package comprising a die and a lead, the die and the lead being spaced apart, a contact pad on a surface of the die, an electrical connection being formed between the contact pad and the lead, the electrical connection comprising a solder surface layer and a high-temperature core, the high-temperature core being laterally surrounded by solder surface layer, the solder surface layer being in contact with the contact pad and the lead such that the high-temperature core is completely enclosed by the lead, the contact pad and the solder surface layer, wherein the high-temperature core has a higher melting temperature than the solder surface layer.

2. The bump-on-leadframe semiconductor package of claim 1 wherein the high-temperature core comprises an electrically conductive material.

3. The bump-on-leadframe semiconductor package of claim 2 wherein the high-temperature core comprises a metal.

4. The bump-on-leadframe semiconductor package of claim 3 wherein the high-temperature core comprises a metal selected from the group consisting of copper, aluminum and the refractory metals.

5. The bump-on-leadframe semiconductor package of claim 1 wherein the high-temperature core comprises an electrically nonconductive material.

6. The bump-on-leadframe semiconductor package of claim 5 wherein the high-temperature core comprises a material selected from the group consisting of the plastics, the ceramic materials and silicon dioxide.

7. The bump-on-leadframe semiconductor package of claim 1 comprising a plurality of the contact pads, a plurality of the electrical connections and a plurality of the leads, wherein each of the contact pads is connected to one of the lead by means of one of the electrical connections.

8. The bump-on-leadframe semiconductor package of claim 7 wherein the package comprises a leaded package wherein the die, the electrical connections and a portion of each of the leads are encapsulated in a plastic material.

9. The bump-on-leadframe semiconductor package of claim 8 wherein each of the leads is a gull-winged lead.

10. The bump-on-leadframe semiconductor package of claim 8 wherein each of the leads is a reverse gull-winged lead.

11. The bump-on-leadframe semiconductor package of claim 8 further comprising a heat slug, the die being connected to the heat slug by means of a connection similar to the electrical connections.

12. The bump-on-leadframe semiconductor package of claim 7 wherein the package comprises a no-lead package wherein the die and the electrical connections are encapsulated in a plastic material and wherein the leads are partially encapsulated in the plastic material, the plastic material being formed in the shape of a rectangular solid, an exposed surface of each of the leads being coplanar with a surface of the plastic material.

13. The bump-on-leadframe semiconductor package of claim 12 wherein a first lead on one side of the package is asymmetrical with respect to a second lead on an opposite side of the package.

14. The bump-on-leadframe semiconductor package of claim 12 further comprising a heat slug, the die being connected to the heat slug by means of a connection similar to the electrical connections.

15. A chip-scale semiconductor package comprising a semiconductor die mounted on a printed circuit board, the die comprising a plurality of contact pads, each of the contact pads being connected to a circuit path in the printed circuit board by means of an electrical connection, each of the electrical connections comprising a solder surface layer and a high-temperature core, the high-temperature core being laterally surrounded by the solder surface layer, the solder surface layer being in contact with the contact pad and the circuit path such that the high-temperature core is completely enclosed by the circuit path, the contact pad and the solder surface layer, wherein the high-temperature core has a higher melting temperature than the solder surface layer.

16. The chip-scale semiconductor package of claim 15 wherein the high-temperature core comprises an electrically conductive material.

17. The chip-scale semiconductor package of claim 16 wherein the high-temperature core comprises a metal.

18. The chip-scale semiconductor package of claim 17 wherein the high-temperature core comprises a metal selected from the group consisting of copper, aluminum and the refractory metals.

19. The chip-scale semiconductor package of claim 15 wherein the high-temperature core comprises an electrically nonconductive material.

20. The chip-scale semiconductor package of claim 19 wherein the high-temperature core comprises a material selected from the group consisting of a plastic material, a ceramic material and silicon dioxide.

21. A method of forming an electrical connection between a contact pad on a semiconductor die and an external circuit path, the method comprising:
providing a solder ball, the solder ball comprising a high-temperature core and a solder shell, the high-temperature core being enclosed by the solder shell, the high-temperature core having a higher melting temperature than the solder shell;
positioning the solder ball such that the solder ball is in contact with the contact pad and the external circuit path; and
heating the solder ball to a temperature above the melting temperature of the solder shell but below the melting temperature of the high-temperature core.

22. The method of claim 21 wherein positioning the solder ball such that the solder ball is in contact with the contact pad and the external circuit path comprises causing the solder ball to rest on the contact pad and causing the external circuit path to rest on the solder ball.

23. The method of claim 22 wherein the contact pad comprises an under bump metal member, the under bump metal member having a concave surface in contact with the solder ball.

24. The method of claim 22 wherein positioning the solder ball such that the solder ball is in contact with the contact pad and the external circuit comprises initially causing the solder ball to rest on the contact pad, then heating the contact pad to melt a portion of the shell and thereby cause the solder ball to adhere to the contact pad, and then causing the external circuit path to rest on the solder ball.

25. The method of claim 21 wherein the high-temperature material is selected from the group consisting of a plastic material, a ceramic material, and silicon dioxide.
